(19) United States
(12) Patent Application Publication
(10) Pub. No.: US 2025/0226840 A1
(43) Pub. Date: Jul. 10, 2025

(54) PROCESSING CIRCUIT FOR ARTIFICIAL NEURAL NETWORK, METHOD OF OPERATING THE PROCESSING CIRCUIT, AND SYSTEM INCLUDING THE SAME

(71) Applicant: Samsung Electronics Co., Ltd., Suwon-si (KR)

(72) Inventors: Son Ngoc PHAM, Seoul-si (KR); Taeweon SUH, Seoul-si (KR)

(73) Assignees: Samsung Electronics Co., Ltd., Suwon-si (KR); KOREA UNIVERSITY RESEARCH AND BUSINESS FOUNDATION, Seoul (KR)

(21) Appl. No.: 18/976,787

(22) Filed: Dec. 11, 2024

(30) Foreign Application Priority Data
Jan. 10, 2024 (KR) 10-2024-0004355
May 9, 2024 (KR) 10-2024-0061261

(51) Int. Cl. H03M 7/30; G06F 17/16

(52) U.S. Cl. CPC H03M 7/6011; G06F 17/16

(57) ABSTRACT

Provided are a processing device configured to compress the output data of a first layer into second compressed input data by extracting non-zero values from the output data of the first layer by using a stride-aware compressed sparse row (SCSR) algorithm based on stride of a second layer in the artificial neural network and output the second compressed input data as input data of the second layer.

### CROSS-REFERENCE TO RELATED APPLICATIONS

This application is based on and claims priority under 35 U.S.C. § 119 to Korean Patent Application Nos. 10-2024-0004355, filed on Jan. 10, 2024, and 10-2024-0061261, filed on May 9, 2024, in the Korean Intellectual Property Office, the disclosures of which are incorporated by reference herein in their entireties.

### BACKGROUND

The inventive concepts relate to an artificial neural network, and more particularly, to a processing circuit for an artificial neural network, a method of operating the processing circuit, and a system including the same.

An artificial neural network may refer to a computing device or a method performed by the computing device to implement interconnected sets of artificial neurons (or neuron models). An artificial neuron may generate output data by performing simple operations on input data, wherein the output data may be passed to another artificial neuron. A deep neural network or deep learning, as an example of the artificial neural network, may have a multi-layer structure.

Since deep learning inference calculations require extensive calculations, the usefulness of the artificial neural network may be limited in a limited environment (such as mobile environments and/or an environment that requires high-speed processing). Accordingly, a method to efficiently compress the input of each layer of the model may be required.

### SUMMARY

The inventive concepts provide a processing device capable of efficiently compressing input of each layer in an artificial neural network, a method of operating the processing device, and a system including the same.

According to an aspect of the inventive concepts, there is provided a processing circuit including a computing circuit configured to generate output data for a first layer in an artificial neural network (ANN), the generating output data for the first layer including performing a convolution operation based on input data of the first layer and weight data of the first layer, and a compressing circuit configured to compress the output data of the first layer into second compressed input data, the compressing of the output data of the first layer including extracting non-zero values from the output data of the first layer based on a stride of a second layer in the artificial neural network and to output the second compressed input data as input data of the second layer, wherein the extracting non-zero values from the output data of the first layer includes using a stride-aware compressed sparse row (SCSR) algorithm, and wherein the second layer is a subsequent layer to the first layer.

According to another aspect of the inventive concepts, there is provided a method of operating a processing circuit, the method including generating output data for a first layer in an artificial neural network by performing a convolution operation based on input data of the first layer and weight data of the first layer, extracting non-zero values from the output data of the first layer, and compressing the output data of the first layer into second compressed input data based on the extracted non-zero values and a stride of a second layer in the artificial neural network, wherein the second layer is a subsequent layer to the first layer.

According to another aspect of the inventive concepts, there is provided a system including at least one processor, and a non-transitory storage medium storing instructions configured to, when executed by the at least one processor, cause the at least one processor to perform a method of compressing output data of a plurality of layers in an artificial neural network, wherein the method of compressing the output data of the plurality of layers in the artificial neural network includes performing a convolution operation based on input data of a first layer in the artificial neural network and weight data of the first layer and generating output data of the first layer, extracting non-zero values from the output data of the first layer, and compressing the output data of the first layer into second compressed input data based on stride of a second layer in the artificial neural network and the extracted non-zero values, wherein the second layer is a subsequent layer to the first layer.

### BRIEF DESCRIPTION OF THE DRAWINGS

Embodiments will be more clearly understood from the following detailed description taken in conjunction with the accompanying drawings in which:

FIG. 1 is a block diagram of a processing circuit according to at least one embodiment;

FIG. 2 is a flowchart of a method of operating a processing circuit according to at least one embodiment;

FIGS. 3A to 3E are diagrams illustrating a method of operating a processing circuit according to at least one embodiment and a method of operating a processing circuit according to a comparative embodiment;

FIGS. 4A and 4B are diagrams illustrating a process of compressing input data and weight data of each layer in an artificial neural network of a processing circuit according to at least one embodiment;

FIG. 5 is a block diagram of a processing circuit according to at least one embodiment;

FIG. 6 is a block diagram of a processing element (PE) according to at least one embodiment;

FIG. 7 is a flowchart of a convolution operation of a processing circuit according to at least one embodiment;

FIG. 8 is a diagram illustrating a convolution operation of a processing circuit according to at least one embodiment;

FIG. 9 shows graphs to compare a processing circuit according to at least one embodiment with a processing circuit according to a comparative embodiment in power consumption and a power consumption percentage of each component of the processing circuit;

FIG. 10 is a block diagram of a computing system according to at least one embodiment; and

FIG. 11 is a block diagram of a portable computing device according to at least one embodiment.

### DETAILED DESCRIPTION OF THE EMBODIMENTS

Hereinafter, embodiments are described in detail with reference to the accompanying drawings.

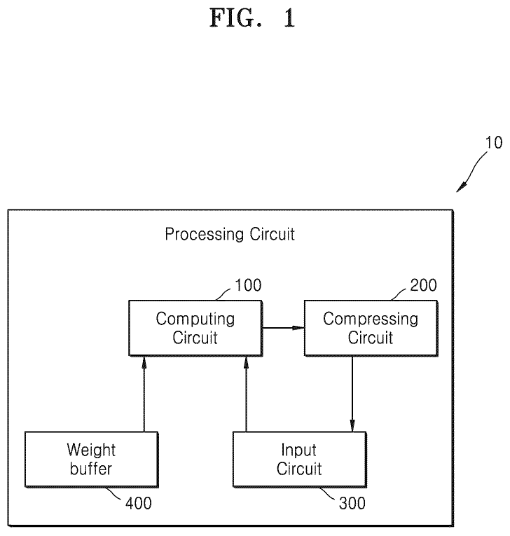

FIG. 1 is a block diagram of a processing circuit according to at least one embodiment.

The functions and/or functional elements that enable said functions described below may be implemented or supported by processing circuitry such as, hardware, software, or a combination of hardware and software. For example, the processing circuitry may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc. For example, the various functions described below may be implemented or supported by artificial intelligence technology or one or more computer programs, each of which consists of computer-readable program code and is implemented on a computer-readable medium. The terms “application” and “program” refer to one or more computer programs, software components, sets of instructions, procedures, functions, objects, classes, instances, associated data, or portions thereof suitable for implementation in suitable computer-readable program code. The term “computer-readable program code” includes all types of computer code, including source code, object code, and executable code. The term “computer-readable medium” includes any type of medium that can be accessed by a computer, such as read-only memory (ROM), random-access memory (RAM), a hard disk drive, a compact disk (CD), a digital video disk (DVD), or any other type of memory. The “non-transitory” computer-readable medium excludes wired, wireless, optical, or other communication links that transmit transient electrical or other signals. The non-transitory computer-readable medium includes a medium in which data can be permanently stored, and a medium in which data can be stored and later overwritten, such as a rewritable optical disk or an erasable memory device.

In some embodiments described below, hardware-based approaches are shown as an example. However, since embodiments include technology using both hardware and software, the embodiments do not exclude software-based (e.g., enabled) approaches.

An artificial neural network (ANN) may refer to a computing system inspired by a biological neural network that makes up the animal brain. Unlike conventional algorithms that perform tasks according to predefined conditions, such as rule-based programming, the ANN may learn to perform tasks by considering multiple samples (or examples). The ANN may have a structure in which artificial neurons (or neurons) are connected, wherein the connection between neurons may be referred to as a synapse. The neurons may process received signals and transmit the processed signals to other neurons through the synapse. The output of neurons may be referred to as activation. Unlike the animal brain, the neuron and/or synapse of the ANN may have a variable weight, and depending on the weight, the influence of signals processed by the neuron may increase or decrease. In particular, the weight associated with individual neurons may be referred to as bias.

The ANN may have a layered structure. For example, the ANN may be (and/or include) a deep neural network (DNN) or deep learning architecture; and the deep neural network (DNN) or deep learning architecture may have a layer structure and the output of a specific layer may become an input of the subsequent layer. For example, the DNN may include, but is not limited to, a convolutional neural network (CNN), a recurrent neural network (RNN), a deep belief network, a restricted Boltzmann machine, and the like. In this multi-layered structure, each of the layers may be trained based on multiple samples. The ANN, such as DNN, may be implemented by multiple processing nodes corresponding to artificial neurons, respectively. To obtain good results, such as results with high accuracy, high computational complexity and many computing resources may be required.

Referring to FIG. 1, the processing circuit 10 according to at least one embodiment includes a computing circuit 100, a compressing circuit 200, an input circuit 300, and a weight buffer 400. The computing circuit 100 may be configured to receive input data of each layer in the ANN from the input circuit 300 and to receive weight data of each layer in the ANN from the weight buffer 400. The computing circuit 100 may be configured to generate output data of each layer in the ANN by performing a convolution operation based on the received input data and weight data. The convolution operation may refer to an operation of performing multiplication on a valid input pair (e.g., a pair of elements of input data and elements of weight data that perform valid multiplication based on stride) and performing accumulation on the result of multiplication. The stride may refer to the amount of movement of weight data in a row direction or a column direction when performing the convolution operation. The input data and the weight data may be formed in a matrix form, e.g., a sparse matrix. The sparse matrix may refer to a matrix in which the value of most elements is 0. When performing the convolution operation on elements with a value of 0, which does not affect the output data, the processing circuit 10 may compress the input data or weight data by extracting elements that do not have a value of 0, that is, elements with non-zero values, from the input data or weight data. When performing the convolution operation on the compressed input data or compressed weight data, computational complexity may be lowered but multiplication may also be performed on input pairs that perform invalid multiplication. Thus, an operation of searching for valid input pairs may be necessary. The operation of searching for valid input pairs may increase power consumption of the processing circuit 10.

To avoid performing the operation of searching for valid input pairs while compressing the input data or weight data, the compressing circuit 200 according to the inventive concepts may be configured to compress the input data and/or weight data by a stride-aware compressed sparse row (SCSR) algorithm based on the stride of each layer in the ANN. The SCSR algorithm may refer to extracting non-zero values from elements of input data or elements of weight data and generating compressed input data and/or compressed weight data by applying Equation 1 below to elements with non-zero values.

$${t}_{f} = {c}_{f}^{o} mod s {t}_{w} = {c}_{w}^{o} mod s \qquad [ Equation 1 ]$$

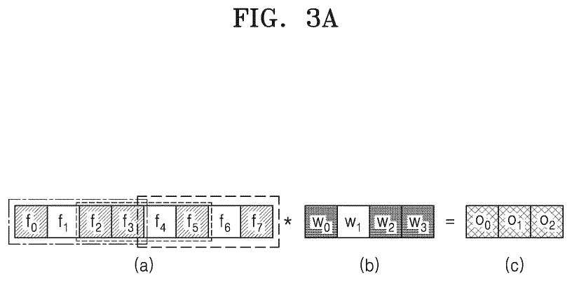

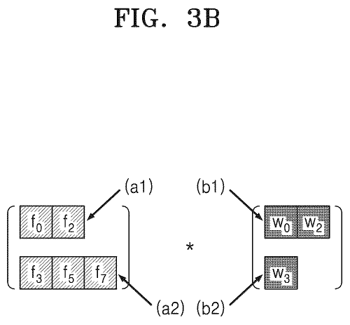

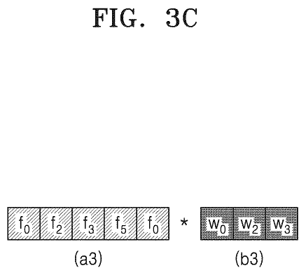

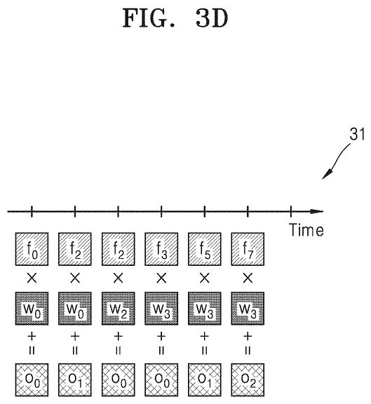

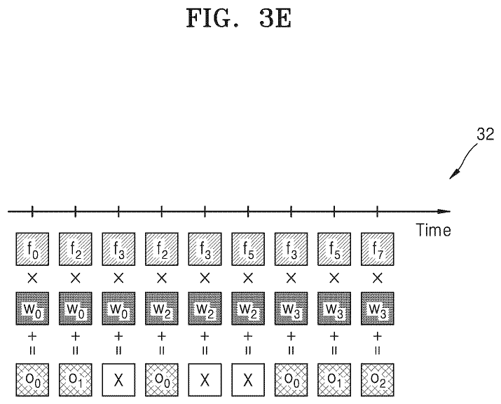

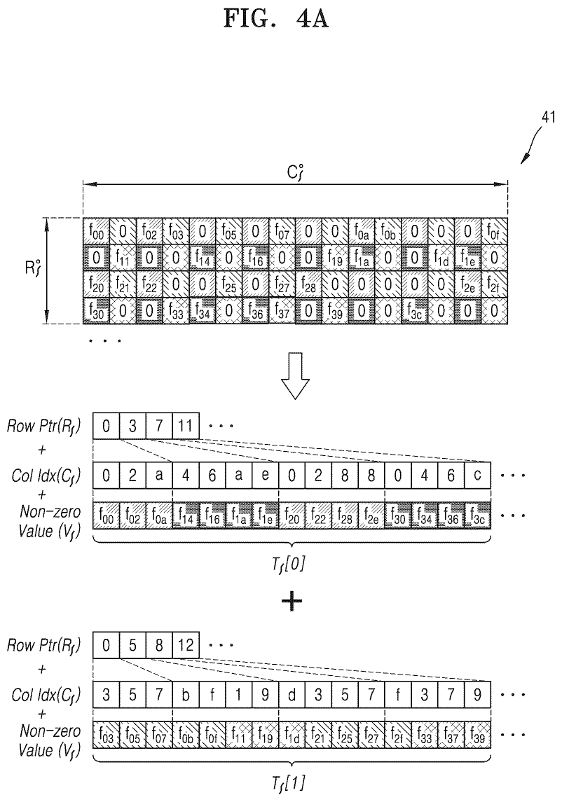

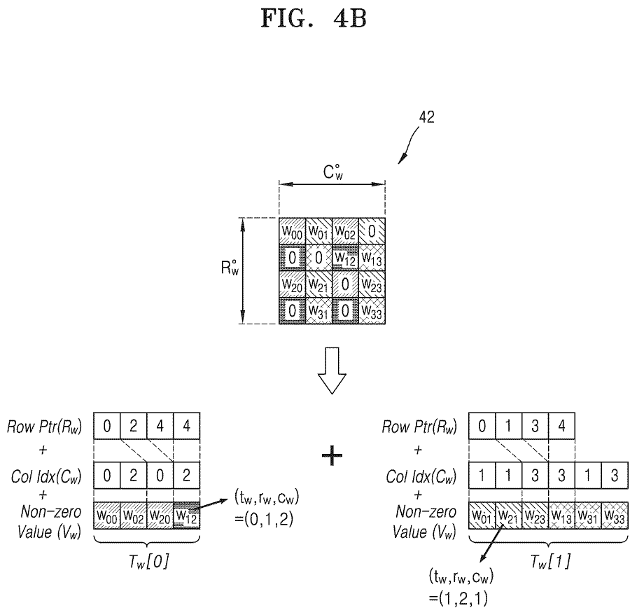

In Equation 1, t_{f} refers to an index of compressed input data; c_{f}⁰ refers to a column index of input data; t_{w} refers to an index of compressed weight data; c_{w}⁰ refers to a column index of weight data; S refers to stride; and mod refers to a mathematical symbol for calculating the remainder. A specific embodiment of generating compressed input data or compressed weight data by applying Equation 1 may be described below with reference to FIGS. 3B, 4A, and 4B.

In some embodiments, the compressing circuit 200 may receive the output data of the specific layer in the ANN from the computing circuit 100 and may compress the output data of the specific layer into compressed input data using the SCSR algorithm based on the stride of the subsequent layer.

For example, the computing circuit 100 may be configured to generate output data of a first layer by performing the convolution operation based on input data of the first layer and weight data of the first layer and may transmit the output data of the first layer to the compressing circuit 200. The compressing circuit 200 may compress the output data of the first layer into second compressed input data by extracting non-zero values from the output data of the first layer using the SCSR algorithm based on stride of a second layer, which is a subsequent layer to the first layer. The second compressed input data may be used as input data of the second layer.

For example, the compressing circuit 200 may compress the output data of the first layer into the same number of pieces of second compressed input data as the stride of the second layer. When the stride of the second layer is 2, the number of pieces of second compressed input data may be 2 and when the stride of the second layer is 3, the number of pieces of second compressed input data may be 3.

For example, the compressing circuit 200 may cause each of the second compressed input data to be composed of elements that, among a plurality of elements of the output data of the first layer, have the same remainder value when the column index of the plurality of elements is divided by the stride of the second layer. When the stride of the second layer is 2, specific compressed input data of the second compressed input data may be composed of elements of which the column index is an even number, among the plurality of elements of the output data of the first layer, and the other compressed input data of the second compressed input data may be composed of elements of which the column index is an odd number, among the plurality of elements of the output data of the first layer.

In some embodiments, the compressing circuit 200 may compress the output data of the specific layer into compressed input data using the SCSR algorithm and transmit the same to the input circuit 300, and the computing circuit 100 may receive the compressed input data from the input circuit 300. The weight buffer 400 may store compressed weight data which is compressed using the SCSR algorithm, and the computing circuit 100 may receive the compressed weight data from the weight buffer 400. The computing circuit 100 may generate output data by performing the convolution operation based on the received compressed input data and compressed weight data.

For example, the compressing circuit 200 may be configured to compress the output data of the first layer into the second compressed input data by using the SCSR algorithm and transmit the same to the input circuit 300. The weight buffer 400 may store the second compressed weight data into which the weight data of the second layer is compressed by using the SCSR algorithm. The computing circuit 100 may receive the second compressed input data from the input circuit 300 and receive the second compressed weight data from the weight buffer 400. The computing circuit 100 may generate output data of the second layer by performing the convolution operation based on the second compressed input data and the second compressed weight data. When the stride of the second layer is 2, the number of pieces of second compressed input data may be 2 and the number of pieces of second compressed weight data may be 2.

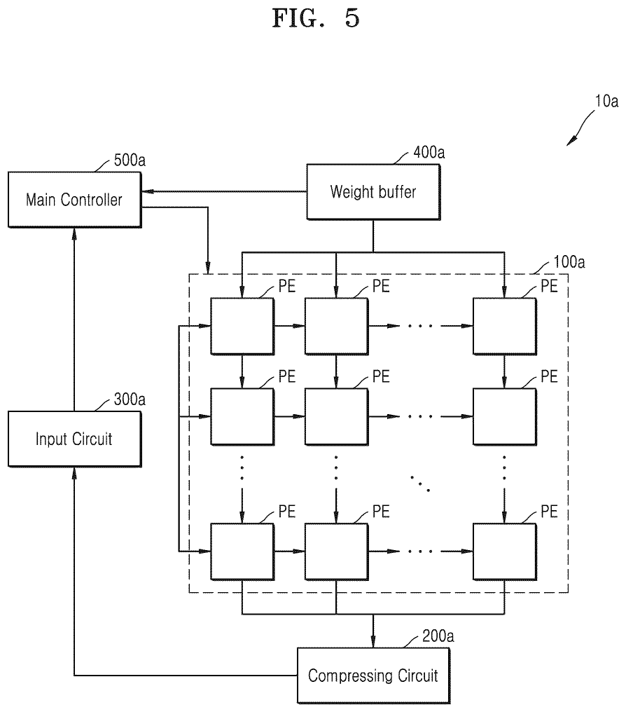

For example, the compressing circuit 200 may be configured to output the same number of pieces of first compressed input data as the stride of the first layer by using the SCSR algorithm and the input circuit 300 may receive and store the first compressed input data. The weight data of the first layer may include the same number of pieces of first compressed weight data as the stride of the first layer generated using the SCSR algorithm and may be stored in the weight buffer 400. The computing circuit 100 may generate the output data of the first layer by performing the convolution operation based on the first compressed input data received from the input circuit 300 and the first compressed weight data received from the weight buffer 400, wherein a specific embodiment of the convolution operation may be described below with reference to FIGS. 5 to 8.

The input circuit 300 may be configured to store the compressed input data, which is compressed by using the SCSR algorithm, as input data of each layer in the ANN. The weight buffer 400 may store the compressed weight data, which is compressed by using the SCSR algorithm, as weight data of each layer in the ANN. The input circuit 300 or the weight buffer 400, which is a non-limiting example, may include volatile memory, such as static random-access memory (SRAM) and dynamic random-access memory (DRAM), and may also include non-volatile memory, such as flash memory.

In FIG. 1, the processing circuit 10 is shown as including the weight buffer 400 but may not be limited thereto. For example, the weight buffer 400 may be configured as separate memory outside the processing circuit 10.

The compressing circuit 200 according to the inventive concepts may compress the output data of each layer by using the SCSR algorithm based on the stride of each layer in the ANN, wherein the compressed output data may be used as input data of the subsequent layer. When using the SCSR algorithm based on the stride of each layer in the ANN, valid input pairs are compressed. Thus, a separate circuit to search for valid input pairs may not be added or a storage space may not be allocated. Accordingly, input data may be compressed without performing an operation of searching for valid input pairs, thereby reducing power consumption of the processing circuit 10 and improving processing speed.

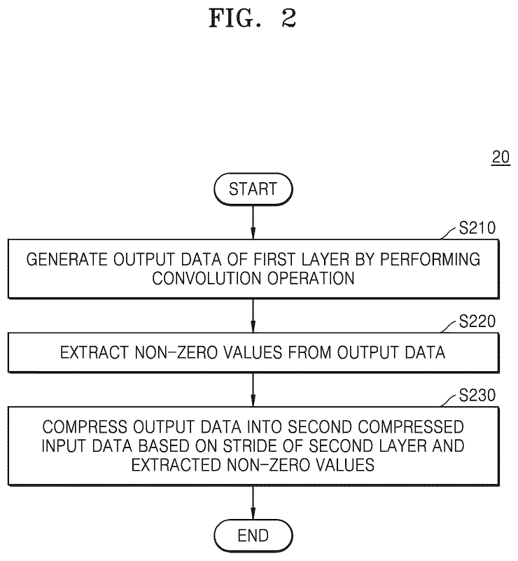

FIG. 2 is a flowchart of a method of operating a processing circuit according to at least one embodiment. Referring to FIG. 2, a method 20 of operating a processing circuit may include a plurality of operations S210 to S230.

Referring further to FIG. 1, in operation S210, the processing circuit 10 may generate the output data of the first layer by performing the convolution operation. In some embodiments, the computing circuit 100 may generate the output data of the first layer by performing the convolution operation based on input data of the first layer and the weight data of the first layer in the ANN. A specific embodiment of the convolution operation may be described below with reference to FIGS. 5 to 8.

In operation S220, the processing circuit 10 may extract non-zero values from the output data. In some embodiments, the compressing circuit 200 may receive the output data of the first layer in the ANN from the computing circuit 100, wherein the output data of the first layer may include a sparse matrix. The compressing circuit 200 may use the SCSR algorithm to extract elements that do not have a value of 0 (e.g., elements with non-zero values) among the elements of the output data of the first layer. For example, the operation of extracting elements with non-zero values by using the SCSR algorithm may be the same as an operation of extracting elements with non-zero values by using a compressed sparse row (CSR) algorithm.

In operation S230, the processing circuit 10 may compress the output data of the first layer into the second compressed input data based on the stride of the second layer, which is the subsequent layer to the first layer, and the extracted non-zero values. The second compressed input data may be used as input data of the second layer.

In some embodiments, the compressing circuit 200 may compress the output data of the first layer into the same number of pieces of second compressed input data as the stride of the second layer. For example, when the stride of the second layer is 2, the number of pieces of second compressed input data may be 2 and when the stride of the second layer is 3, the number of pieces of second compressed input data may be 3.

In some embodiments, the compressing circuit 200 may cause each of the second compressed input data to be composed of elements that, among the plurality of elements of the output data of the first layer, have the same remainder value when the column index of the plurality of elements is divided by the stride of the second layer. For example, when the stride of the second layer is 2, specific compressed input data of the second compressed input data may be composed of elements of which the column index is an even number, among the plurality of elements of the output data of the first layer, and the other compressed input data of the second compressed input data may be composed of elements of which the column index is an odd number, among the plurality of elements of the output data of the first layer.

In some embodiments, the method may further include, prior to operation S210, extracting non-zero values from output data of a previous layer to the first layer and compressing the output data of the previous layer into first compressed input data based on the non-zero values extracted from the output data of the previous layer and the stride of the first layer. For example, the input data of the first layer may include the same number of pieces of first compressed input data as the stride of the first layer output by the compressing circuit 200 using the SCSR algorithm.

In some embodiments, the method may further include training the ANN before operation S210. The training of the ANN may refer to generating weight data of each layer in the ANN. For example, in the training of the ANN, the weight data of the first layer may include the same number of pieces of first compressed weight data as the stride of the first layer generated by using the SCSR algorithm based on the stride of the first layer.

FIGS. 3A to 3E are diagrams illustrating a method of operating a processing circuit according to at least one embodiment and a method of operating a processing circuit according to a comparative embodiment.

FIG. 3A is a graph illustrating a process of generating one-dimensional output data (c) by performing a convolution operation on one-dimensional input data (a) and one-dimensional weight data (b) of a specific layer in an uncompressed ANN. The stride of the specific layer may be assumed to be 2. The one-dimensional input data (a) may include elements with a value of 0 (e.g., f₁, f₄, and f₆), and one-dimensional weight data (b) may include an element with a value of 0 (e.g., W₁).

When performing the convolution operation on elements with a value of 0, which does not affect the output data, the processing circuit 10 in FIG. 1 may compress the input data or the weight data by extracting elements that do not have a value of 0 (e.g., elements with non-zero values) from the input data or the weight data.

FIG. 3B is a diagram illustrating an operation of compressing input data and weight data of a specific layer in an ANN of a processing circuit, by using the SCSR algorithm, according to at least one embodiment. Referring further to FIG. 1, the compressing circuit 200 may compress the one-dimensional data (a) into two one-dimensional compressed input data (a1 and a2) by extracting non-zero values (e.g., f₀, f₂, f₃, f₅, and f₇) from the one-dimensional input data (a) by using the SCSR algorithm based on the stride of the specific layer.

For example, a plurality of elements of the one-dimensional input data (a) may have a column index of 0 to 7 in order from the first element f₀ to the eighth element f₇. The one-dimensional compressed input data (a1) may be composed of elements (e.g., f₀ and f₂) that, among the plurality of elements of the one-dimensional input data (a), have non-zero values by using Equation 1 of FIG. 1 and a remainder value of 0 when the column index of the plurality of elements is divided by 2, which is the stride of the specific layer. Since the remainder value is 0, the index of the one-dimensional compressed input data (a1) may be 0. The one-dimensional compressed input data (a2) may be composed of elements (e.g., f₃, f₅, and f₇) that, among the plurality of elements of the one-dimensional input data (a), have non-zero values by using Equation 1 of FIG. 1 and a remainder value of 1 when the column index of the plurality of elements is divided by 2, which is the stride of the specific layer. Since the remainder value is 1, the index of the one-dimensional compressed input data (a2) may be 1.

The one-dimensional weight data (b) may be compressed into two one-dimensional compressed weight data (b1 and b2) by using the SCSR algorithm based on the stride of the specific layer. For example, a plurality of elements of the one-dimensional weight data (b) may have a column index of 0 to 3 in order from the first element W₀ to the fourth element W₃. The one-dimensional compressed weight data (b1) may be composed of elements (e.g., W₀ and W₂) that, among the plurality of elements of the one-dimensional weight data (b), have non-zero values by using Equation 1 of FIG. 1 and a remainder value of 0 when the column index of the plurality of elements is divided by 2, which is the stride of the specific layer. Since the remainder value is 0, the index of the first compressed weight data (b1) may be 0. The one-dimensional compressed weight data (b2) may be composed of an element (e.g., W₃) that, among the plurality of elements of the one-dimensional weight data (b), has a non-zero value by using Equation 1 of FIG. 1 and a remainder value of 1 when the column index of the plurality of elements is divided by 2, which is the stride of the specific layer. Since the remainder value is 1, the index of the first compressed weight data (b2) may be 1.

FIG. 3C is a diagram illustrating an operation of compressing input data and weight data of a specific layer in an ANN of a processing circuit, by using the CSR algorithm, according to a comparative embodiment. The processing circuit according to a comparative embodiment may compress the one-dimensional input data (a) into one-dimensional compressed input data (a3) by extracting non-zero values (e.g., f₀, f₂, f₃, f₅, and f₇) from the one-dimensional input data (a) by using the CSR algorithm and may compress the one-dimensional weight data (b) into one-dimensional compressed weight data (b3) by extracting non-zero values (e.g., Wo, W₂, and W₃) from the one-dimensional weight data (b).

FIG. 3D is a diagram illustrating a convolution operation for compressed input data and compressed weight data of a processing circuit according to at least one embodiment and FIG. 3E is a diagram illustrating a convolution operation for compressed input data and compressed weight data of a processing circuit according to a comparative embodiment. A graph 31 of FIG. 3D may show a convolution operation for elements of the first compressed input data (a1 and a2) and elements of the first compressed weight data (b1 and b2) over time and a graph 32 of FIG. 3E may show a convolution operation for elements of the one-dimensional compressed input data (a3) and elements of the one-dimensional compressed weight data (b3) over time.

When referring to the graph 31, the pair of elements of the first compressed input data (a1 and a2) and elements of the first compressed weight data (b1 and b2) is a valid input pair that performs valid multiplication. Accordingly, output data generated by performing multiplication on the valid input pair and performing accumulation on the multiplication result may be the same as the one-dimensional output data (c) of FIG. 3A.

In contrast, referring to the graph 32, the pair of elements of the one-dimensional compressed input data (a3) and elements of the one-dimensional compressed weight data (b3) may include an input pair that performs invalid multiplication. For example, since the stride of the specific layer is 2, the multiplication of the element f₃ of the one-dimensional compressed input data (a3) and the element Wo of the one-dimensional compressed weight data (b3) may be invalid, the multiplication of the element f₃ of the one-dimensional compressed input data (a3) and the element W₂ of the one-dimensional compressed weight data (b3) may be invalid, and the multiplication of the element f₅ of the one-dimensional compressed input data (a3) and the element W₂ of the one-dimensional compressed weight data (b3) may be invalid. Accordingly, since the multiplication can be performed on invalid input pairs, the output data may be different from the one-dimensional output data (c) of FIG. 3A.

In other words, the processing device according to a comparative embodiment may perform multiplication even on input pairs that perform invalid multiplication. Thus, the output data generated without performing compression may be different from the output data generated after performing compression. Accordingly, the processing device according to a comparative embodiment may require an operation of searching for valid input pairs and the power consumption for the operation of searching for valid input pairs may increase.

On the contrary, the processing device according to at least one embodiment may not perform the operation of searching for valid input pairs since the processing device compresses input data or weight data by using the SCSR algorithm based on the stride of the specific layer and may not add a separate circuit to search for valid input pairs or may not allocate a storage space. Accordingly, since the input data and/or the weight data can be compressed without performing the operation of searching for valid input pairs, the processing speed may be improved while reducing the power consumption of the processing circuit according to at least one embodiment.

FIGS. 4A and 4B are diagrams illustrating a process of compressing input data and weight data of a specific layer in an ANN of a processing circuit according to at least one embodiment.

FIG. 4A is a diagram illustrating an operation of compressing input data of a specific layer in an ANN using the SCSR algorithm based on the stride of a specific layer of a processing circuit according to at least one embodiment. The input data 41 of the specific layer may show first to fourth rows of a sparse matrix formed in the form of a 16×16 matrix and the stride of the specific layer may be 2.

In some embodiments, referring further to FIG. 1, the compressing circuit 200 may compress the input data 41 into two pieces of compressed input data T_{f}[0] and T_{f}[1] by extracting non-zero values from the input data 41, using the SCSR algorithm based on the stride of the specific layer.

For example, the compressed input data T_{f}[0] may be composed of elements that, among the plurality of elements of the input data 41, have non-zero values by using Equation 1 of FIG. 1 and a remainder value of 0 when the column index C_{f}² of the plurality of elements is divided by 2, which is the stride of the specific layer. Since the remainder value is 0, the index of the compressed input data T_{f}[0] may be 0. The compressed input data T_{f}[0] may include a row pointer R_{f} indicating a row address of the input data 41, a column index C_{f} indicating a column address of the input data 41, and a non-zero value V_{f}. The non-zero value V_{f} may be arranged so that elements with the same row index of the input data 41 are adjacent to each other. For example, the elements f₀₀, f₀₂, and f₀ₐ of which the row index R_{f}^{e} of the input data 41 is 0 may be referred to as a first sub-tensor of the compressed input data T_{f}[0], the elements f₁₄, f₁₆, f₁ₐ, and f^{1e} of which the row index R_{f}^{e} of the input data 41 is 1 may be referred to as a second sub-tensor of the compressed input data T_{f}[0], the elements f₂₀, f₂₂, f₂₈, and f₂ₑ of which the row index R_{f}^{e} of the input data 41 is 2 may be referred to as a third sub-tensor of the compressed input data T_{f}[0], and the elements f₃₀, f₃₄, f₃₆, and f_{3c} of which the row index R_{f}^{e} of the input data 41 is 3 may be referred to as a fourth sub-tensor of the compressed input data T_{f}[0].

For example, the compressed input data T_{f}[1] may be composed of elements that, among the plurality of elements of the input data 41, have non-zero values by using Equation 1 of FIG. 1 and a remainder value of 1 when the column index % of the plurality of elements is divided by 2, which is the stride of the specific layer. Since the remainder value is 1, the index of the compressed input data T_{f}[1] may be 1. The compressed input data T_{f}[1] may include a row pointer R_{f} indicating a row address of the input data 41, a column index C_{f} indicating a column address of the input data 41, and a non-zero value V_{f}. The non-zero value V_{f} may be arranged so that elements with the same row index of the input data 41 are adjacent to each other. For example, the elements f₀₃, f₀₅, f₀₇, f_{0b}, and f_{0f} of which the row index R_{f}^{f} of the input data 41 is 0 may be referred to as a first sub-tensor of the compressed input data T_{f}[1], the elements f₁₁, f₁₉, and f₁ₑ of which the row index R_{f}^{c} of the input data 41 is 1 may be referred to as a second sub-tensor of the compressed input data T_{f}[1], the elements f₂₁, f₂₅, f₂₇, and f_{2f} of which the row index R_{f}^{c} of the input data 41 is 2 may be referred to as a third sub-tensor of the compressed input data T_{f}[1], and the elements f₃₃, f₃₇, and f₃₉ of which the row index R_{f}^{a} of the input data 41 is 3 may be referred to as a fourth sub-tensor of the compressed input data T_{f}[1].

FIG. 4A is a diagram illustrating an operation of compressing weight data of a specific layer in an ANN by using the SCSR algorithm based on the stride of the specific layer of a processing circuit according to at least one embodiment. The weight data 42 of the specific layer may show a sparse matrix formed in the form of a 4×4 matrix and the stride of the specific layer may be 2.

In some embodiments, referring further to FIG. 1, the compressing circuit 200 may compress the weight data 42 into two compressed weight data T_{w}[0] and T_{w}[1] by extracting non-zero values from the weight data 42, using the SCSR algorithm based on the stride of the specific layer.

For example, the compressed weight data T_{w}[0] may be composed of elements that, among the plurality of elements of the weight data 42, have non-zero values by using Equation 1 of FIG. 1 and a remainder value of 0 when the column index C_{w}^{o} of the plurality of elements is divided by 2, which is the stride of the specific layer. Since the remainder value is 0, the index of the compressed weight data T_{w}[0] may be 0. The compressed weight data T_{w}[0] may include a row pointer R_{w} indicating a row address of the weight data 42, a column index C_{w} indicating a column address of the weight data 42, and a non-zero value V_{w}. The non-zero value V_{w} may be arranged so that elements with the same row index R_{w}^{o} of the weight data 42 are adjacent to each other.

$${r}_{w} = ( {r}_{w}^{o} mod s ) \times s + floor ( {r}_{w}^{o} / s ) \qquad [ Equation 2 ]$$

In Equation 2, r_{w} is a row index value of the compressed weight data; and r_{w}⁰ is a row index value of the weight data. mod may refer to a mathematical symbol for calculating the remainder and floor may refer to a mathematical symbol for rounding down. For example, the elements W₀₀, W₀₂, and W₂₀ of which the row index R_{f}^{o} of the weight data 42 is an odd number are sequentially arranged and then the element W₁₂ of which the row index R_{f}^{o} of the weight data 42 is an even number is arranged.

For example, the compressed weight data T_{w}[1] may be composed of elements that, among the plurality of elements of the weight data 42, have non-zero values by using Equation 1 of FIG. 1 and a remainder value of 1 when the column index C_{w}^{o} of the plurality of elements is divided by 2, which is the stride of the specific layer. Since the remainder value is 1, the index of the compressed weight data T_{w}[1] may be 1. The compressed weight data T_{w}[1] may include a row pointer R_{w} indicating a row address of the weight data 42, a column index C_{w} indicating a column address of the weight data 42, and a non-zero value V_{w}. The non-zero value V_{w} may be arranged so that the row index of the weight data 42 satisfies Equation 2 above. For example, the elements W₀₁, W₂₁, and W₂₃ of which the row index R of the weight data 42 is an odd number are sequentially arranged and then the elements W₁₃, W₃₁, and W₃₃ of which the row index R_{f}^{o} of the weight data 42 is an even number are arranged.

When Equation 2 above is satisfied and the convolution operation on the input data 41 and the weight data 42 of FIG. 4A is performed, invalid multiplication (e.g., multiplication of foo and W₂₀) at the boundary portion may be reduced or prevented. Thus, the processing device according to the inventive concepts may skip (e.g., not perform) the operation of searching for valid input pairs. Accordingly, the processing device according to the inventive concepts may improve the processing speed while reducing the power consumption. Additionally, the improved speed and/or reduced power consumption may allow for implementation of the ANN in limited environments (such as mobile environments and/or an environment that requires high-speed processing), in which the comparative example would not be suited due to the comparatively greater processing speed and/or power consumption. Additionally, the reduced power consumption may reduce heat production in the processing device, thereby improving the performance of the processing device by mitigating and/or delaying performance degradation due to overheating.

In some embodiments, the weight data 42 may be pre-compressed into the compressed weight data T_{w}[0] and T_{w}[1]. For example, in the training of the ANN, before generating output data of each layer within the ANN, the weight data 42 may be compressed into the compressed weight data T_{w}[0] and T_{w}[1] by using the SCSR algorithm based on the stride of the specific layer.

In some embodiments, the input data 41 may be compressed into the compressed input data T_{f}[0] and T_{f}[1] in an inference operation of the ANN. The inference operation may refer to an operation of generating output data of each layer in the ANN.

FIG. 5 is a block diagram of a processing circuit according to at least one embodiment.

Referring to FIG. 5, in some embodiments, the processing circuit 10a may include at least one embodiment of the processing circuit 10 of FIG. 1. The processing circuit 10a may include a computing circuit 100a, a compressing circuit 200a, an input circuit 300a, a weight buffer 400a, and a main controller 500a, wherein the compressing circuit 200a, the input circuit 300a, and the weight buffer 400a may respectively be the same as (and/or substantially similar to) the compressing circuit 200, the input circuit 300, and the weight buffer 400 of FIG. 1. Overlapping descriptions with FIG. 1 may be omitted.

The computing circuit 100a may include a plurality of processing elements (PEs) arranged in a matrix form. In some embodiments, the computing circuit 100a may include the plurality of PEs arranged in a matrix (e.g., a 16×16 matrix). Among the plurality of PEs, PEs having the same row index may receive the same compressed input data from the input circuit 300a and PEs having the same column index may receive the same compressed weight data from the weight buffer 400a. An operation of transmitting the same data to the plurality of PEs may be referred to as broadcasting. For example, PEs with a row index of 0 (e.g., PEs arranged in a first row) may receive the same compressed input data from the input circuit 300a and PEs with a column index of 0 (e.g., PEs arranged in a first column) may receive the same compressed weight data from the weight buffer 400a. Since PEs arranged in the same row or the same column receive the same input, the number of times to access memory (e.g., input circuit 300a or weight buffer 400a) may be reduced, thereby improving the processing speed of PEs.

The main controller 500a may receive the compressed input data from the input circuit 300a and generate (or calculate) a start element r_{w}^{start} and an end element r_{w}^{end} of the compressed weight data based on the compressed input data. To generate the output data of the specific layer, the convolution operation may be performed on the compressed input data and the compressed weight data of the specific layer, wherein the convolution operation may refer to a two-dimensional convolution operation. The start element r_{w}^{start} and the end element r_{w}^{end} of the compressed weight data may refer to a start index and an end index among row indices of the elements of the compressed weight data that form a valid input pair with the compressed input data of the specific layer in the two-dimensional convolution operation. In some embodiments, the main controller 500a may calculate the start element r_{w}^{start} and the end element r_{w}^{end} of the compressed weight data using a first algorithm based on the compressed input data. The first algorithm may be as shown in Table 1 below.

TABLE 1

```
    input: r_{f} − compressed feature row index
            s − stride
            R_{w}^{o} − weight matrix height
            R_{f}^{o} − feature matrix height
    output: r_{w}^{start} , r_{w}^{end}
  1. if (R_{f}^{o} − r_{f} < R_{w}^{o})
  2. | r_{w}^{start} = (r_{f}mods) ×s+floor ((R_{w}^{o} − R_{f}^{o} + r_{f}) /s)
  3. else
  4. | r_{w}^{start} = (r_{f}mods) × s
  5. end if
  6. if (r_{f} < R_{w}^{o} − 1)
  7. | r_{w}^{end} = (r_{f}mods) × s + floor (r_{f}/s)
  8. else
  9. | r_{w}^{end} = ((r_{f}mods) + 1) × s − 1
10. end if
```

The first algorithm may refer to an operation of receiving inputs, performing calculations from row 1 to row 10, and generating outputs.

The main controller 500a may calculate a small array Sel[ ] based on the compressed input data. To generate the output data of the specific layer, the convolution operation may be performed on the compressed input data and the compressed weight data of the specific layer, wherein the convolution operation may refer to a two-dimensional convolution operation. The small array Sel[ ] may refer to an array for selecting an initial value of an input counter cnt_{f}. The range of the input counter cnt_{f} may include a range between a start element c_{f}^{start} and an end element c_{f}^{end} of the compressed input data, wherein the start element c_{f}^{start} and the end element c_{f}^{end} of the compressed input data may respectively refer to the start index and the end index among the column indices of the elements of the compressed input data that form a valid input pair with the compressed weight data of the specific layer in the two-dimensional convolution operation. For example, the start element of the compressed weight data may refer to an element with a smallest row index among the valid elements of the compressed input data and the end element of the compressed weight data may refer to an element with a largest row index among the valid elements of the compressed input data.

In some embodiments, the main controller 500a may calculate the small array Sel[ ] using a second algorithm based on the compressed input data. The second algorithm may be as shown in Table 2 below.

TABLE 2

```
  input: C_{f} − feature column indices
          C_{w}^{o} − weight matrix length
  output: Sel [0 : C_{w}^{o} − 1]
1. int cnt = 0
2. for (i = 0; i < C_{w}^{o} − 1; i + +)
3. | Sel [i] = cnt
4. | if (C_{f} [cnt] == i)
5. | | cnt + = 1
6. | end if
7. end for
```

The second algorithm may refer to an operation of receiving inputs, performing calculations from row 1 to row 7, and generating outputs. The main controller 500a may transmit the calculated small array Sel[ ], and the start element r_{w}^{start} and the end element r_{w}^{end} of the compressed weight data to the plurality of PEs included in the computing circuit 100a.

In some embodiments, the output data of the specific layer generated by the computing circuit 100a may be transmitted as an activation function (not shown) and a pooling layer (not shown), where nonlinear conversion and downsampling are performed, and may be transmitted to the compressing circuit 200a. The activation function may include a nonlinear function, such as a rectified linear unit (ReLU), a parametric rectified linear unit (PRELU), hyperbolic tangent (tan h), or sigmoid function, and the downsampling may refer to an operation of reducing the size of data. For example, the output data of the specific layer may be transmitted as an activation function (not shown) and a pooling layer (not shown), converted nonlinearly, reduced in size, and transmitted to the compressing circuit 200a.

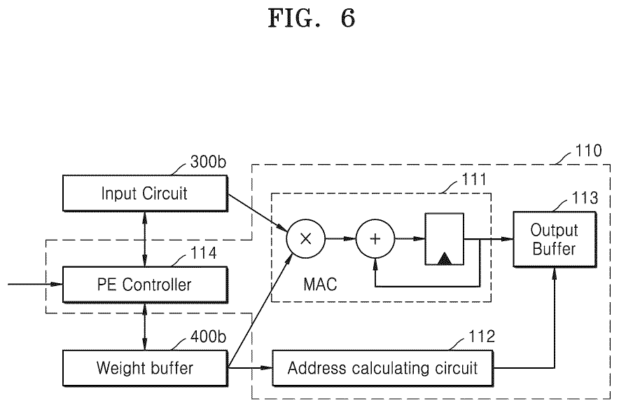

FIG. 6 is a block diagram of a PE according to at least one embodiment.

Referring to FIG. 6, a PE 110 may include at least one embodiment of the configuration of each of the plurality of PEs in FIG. 5 and an input circuit 300b and a weight buffer 400b may respectively be the same as the input circuit 300a and the weight buffer 400a in FIG. 5. Overlapping descriptions with FIG. 5 are omitted. The PE 110 may include a multiply-accumulate (MAC) circuit 111, an address calculating circuit 112, an output buffer 113, and a PE controller 114.

The MAC circuit 111 may generate output data by performing multiplication and accumulation based on the compressed input data received from the input circuit 300b and the compressed weight data received from the weight buffer 400b. In some embodiments, the MAC circuit 111 may receive the compressed input data T_{f}[0] and T_{f}[1] of FIG. 4A from the input circuit 300b and may receive the compressed weight data T_{w}[0] and T_{w}[1] of FIG. 4B from the weight buffer 400b. The MAC circuit 111 may generate the output data by performing multiplication and accumulation based on the compressed input data T_{f}[0] and T_{f}[1] of FIG. 4A and the compressed weight data T_{w}[0] and T_{w}[1] of FIG. 4B.

The address calculating circuit 112 may calculate the address of the output data based on an address signal of the compressed input data received from the input circuit 300b. For example, the address calculating circuit 112 may calculate the address of the output data to correspond to the address signal of the compressed input data.

The output buffer 113 may receive the address of the output data from the address calculating circuit 112 and may receive the output data from the MAC circuit 111. The output buffer 113 may map the address of the received output data to the output data and store the same.

The PE controller 114 may control the input circuit 300b to transmit valid elements of the compressed input data to the MAC circuit 111 and may control the weight buffer 400b to transmit valid elements of the compressed weight data to the MAC circuit 111.

In some embodiments, the PE controller 114 may receive the small array Sel[ ], and the start element r_{w}^{start} and the end element r_{w}^{end} of the compressed weight data from the main controller 500a of FIG. 5 and may calculate the input counter cnt_{f} and the weight counter cnt_{w} by using a convolution algorithm based on the small array Sel[ ], and the start element r_{w}^{start} and the end element r_{w}^{end} of the compressed weight data. The convolution algorithm may be as shown in Table 3 below.

TABLE 3

```
      input: r_{w}^{start},r_{w}^{end}
                  Sel[0 : C_{w}^{o} − 1]
                  C_{f}^{o} , C_{w}^{o}
                  T_{w}
      output: cnt_{w}, cnt_{f}
1. cnt_{w} = find_index(T_{w}, r_{w}^{start} )
2. while cnt_{w} ≤ find_index(T_{w}, R_{w}^{end} )
3. | r_{w} ≤ find_column(T_{w}, cnt_{w})
4. | cnt_{f} = Sel[r_{w}]
5. | while cnt_{f} ≤ C_{f}^{o} − C_{w}^{o} + r_{w}
6. | | cnt_{f} += 1
7. | end while
8. | cnt_{w} += 1
9. end while
```

The convolution algorithm may refer to an operation of receiving inputs, performing calculations from row 1 to row 9, and generating outputs.

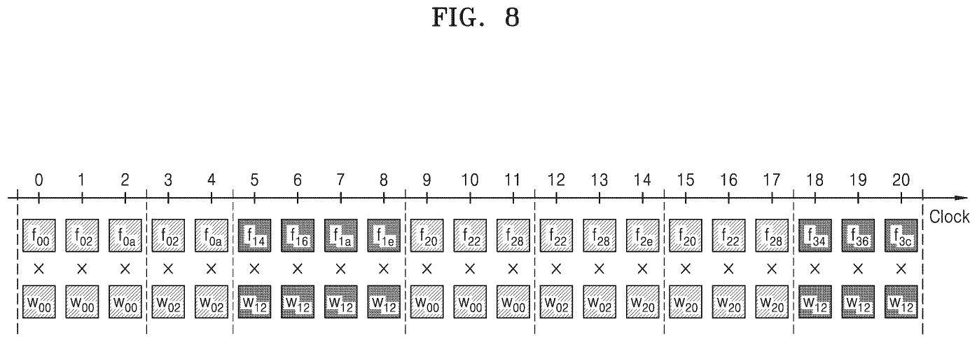

In some embodiments, the PE controller 114 may be configured to control the input circuit 300b and the weight buffer 400b to transmit the elements of the compressed input data and the elements of the compressed weight data that are a valid input pair to the MAC circuit 111 based on the input counter cnt_{f} and the weight counter cnt_{w}. A specific embodiment in which the PE controller 114 controls the input circuit 300b and the weight buffer 400b based on the input counter cnt_{f} and the weight counter cnt_{w} may be described below with reference to FIG. 8.

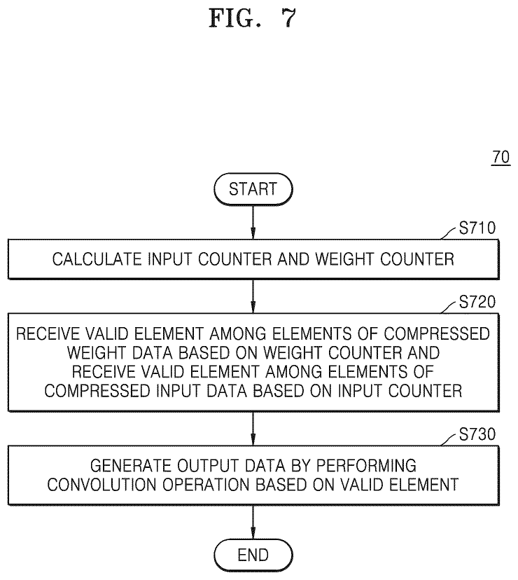

FIG. 7 is a flowchart of a convolution operation of a processing circuit according to at least one embodiment. FIG. 8 is a diagram illustrating a convolution operation of a processing circuit according to at least one embodiment. Referring to FIG. 7, the convolution operation 70 of the processing circuit may include a plurality of operations S710 to S730. Referring further to FIG. 8, the graph 80 may represent a convolution operation for elements of the compressed input data T_{f}[0] and elements of the compressed weight data T_{w}[0] of FIG. 4A according to the clock.

Referring further to FIGS. 5 and 6, in operation S710, the processing circuit 10a may calculate the input counter cnt_{f} and the weight counter cnt_{w}. In some embodiments, the PE controller 114 may receive the small array Sel[ ], and the start element r_{w}^{start} and the end element r_{w}^{end} of the compressed weight data from the main controller 500a and may calculate the input counter cnt_{f} and the weight counter cnt_{w} by using Table 3 which is the convolution algorithm based on the small array Sel[ ], and the start element r_{w}^{start} and end element r_{w}^{end} of the compressed weight data.

In operation S720, the MAC circuit 111 may receive a valid element, among the elements of the compressed weight data, based on the weight counter cnt_{w} and receive a valid element, among the elements of the compressed input data, based on the input counter cnt_{f}.

In some embodiments, the PE controller 114 may control the weight buffer 400b so that the MAC circuit 111 receives the valid element, among the elements of the compressed weight data, based on the weight counter cnt_{w} and may control the input circuit 300b so that the MAC circuit 111 receives the valid element, among the elements of the compressed input data, based on the input counter cnt_{f}.

For example, the MAC circuit 111 may receive an element W₀₀ of the compressed weight data T_{w}[0] from the weight buffer 400b and the PE controller 114 may control the input circuit 300b so that the MAC circuit 111 receives elements f₀₀, f₀₂, and f₀ₐ of the compressed input data T_{f}[0] forming a valid input pair with the element W₀₀, based on the input counter cnt_{f}. When there is no element of the compressed input data that forms a valid input pair with the element W₀₀, the PE controller 114 may control the weight buffer 400b so that the MAC circuit 111 receives a subsequent element W₀₂ to the element W₀₀ among the valid elements of the compressed weight data T_{w}[0] at the third clock (clock 2), based on the weight counter cnt_{w}. The PE controller 114 may control the input circuit 300b so that the MAC circuit 111 receives elements f₀₂ and f₀ₐ of the compressed input data T_{f}[0] that form a valid input pair with the element W₀₂, based on the input counter cnt_{f}. When there is no element of the compressed input data that forms a valid input pair with the element W₀₂, the PE controller 114 may control the weight buffer 400b so that the MAC circuit 111 receives a subsequent element W₁₂ to the element W₀₂ among the valid elements of the compressed weight data T_{w}[0] at the fifth clock (clock 4), based on the weight counter cnt_{w}. In other words, the PE controller 114 may sequentially control the weight buffer 400b and the input circuit 300b so that the MAC circuit 111 receives the valid input pair.

In operation S730, the MAC circuit 111 may generate output data by performing the convolution operation based on valid elements. For example, in the graph 80, the output data may be generated by performing multiplication on a valid input pair at every clock from the first clock (clock 0) to the 21^{st} clock (clock 20) and accumulating the multiplication results.

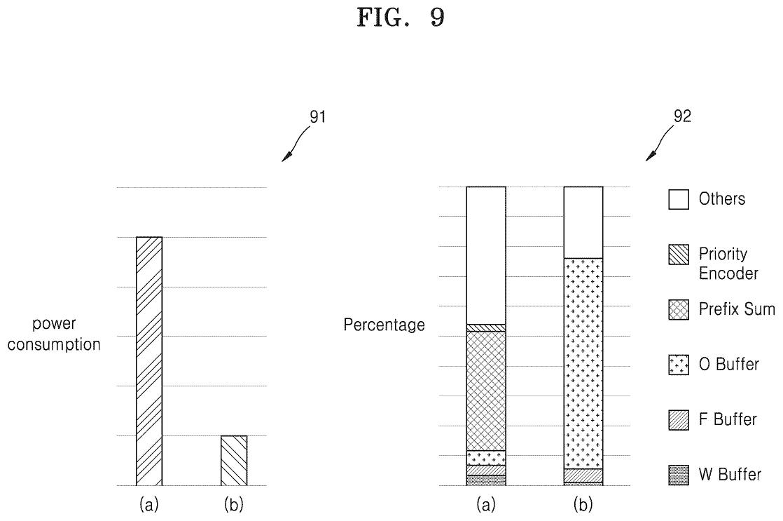

FIG. 9 shows graphs to compare a processing circuit according to at least one embodiment with a processing circuit according to a comparative embodiment in power consumption and a power consumption percentage of each component of the processing circuit.

Referring to FIG. 9, the graph 91 compares the power consumption when the processing circuit of a comparative embodiment compresses the input data or the weight data of the specific layer by using the compression algorithm (a) (e.g., CSR) with the power consumption when the processing circuit according to at least one embodiment compresses the input data or the weight data of the specific layer by using the SCSR algorithm (b) based on the stride of the specific layer. The vertical axis of the graph 91 may represent the power consumption and the horizontal axis thereof may represent the compression method. It can be seen that the power consumption when using the compression algorithm (a) is 5 times greater than when using the SCSR algorithm (b). In other words, when using the SCSR algorithm (b), the power consumption of the processing circuit may be reduced.

The graph 92 shows a power consumption percentage of each component of the processing circuit according to each compression method. Since the processing circuit requires the operation of searching for valid input pairs when using the compression algorithm (a), a significant portion of the power consumption may be taken up by a separate circuit (e.g., prefix sum or priority encoder) to search for valid input pairs. On the contrary, since the processing circuit does not require the operation of searching for valid input pairs when using the SCSR algorithm (b), a significant portion of the power consumption may be allocated to buffers (e.g., output buffer, input buffer, and weight buffer). Accordingly, when using the SCSR algorithm (b), the operation of searching for valid input pairs is omitted, thereby reducing the power consumption and improving the processing speed.

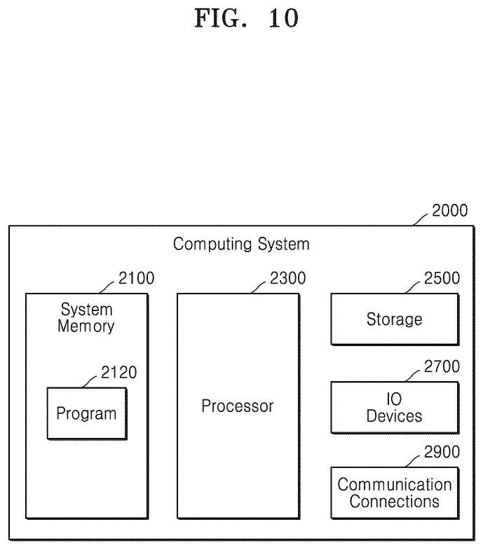

FIG. 10 is a block diagram of a computing system according to at least one embodiment.

In some embodiments, the processing circuit 10 of FIG. 1 may be implemented as a computing system 2000 of FIG. 10. As shown in FIG. 10, the computing system 2000 may include a system memory 2100, a processor 2300, storage 2500, input/output devices 2700, and communication connections 2900. The components included in the computing system 2000 may be connected to each other communicatively, for example, through bus.

The system memory 2100 may include a program 2120. The program 2120 may cause the processor 2300 to perform quantization of the ANN according to some embodiments. For example, the program 2120 may include a plurality of instructions that are executable by the processor 2300. As the plurality of instructions included in the program 2120 are executed by the processor 2300, the output data of each layer may be compressed into the input data of the subsequent layer by using the SCSR algorithm based on the stride of each layer in the ANN. As a non-limiting example, the system memory 2100 may include volatile memory, such as SRAM and DRAM, and non-volatile memory, such as flash memory.

The processor 2300 may include at least one core capable of executing any instruction set (e.g., Intel Architecture-32 (IA-32), 64-bit extended IA-32, x86-64, PowerPC, Sparc, MIPS, ARM, IA-64, etc.). The processor 2300 may execute instructions stored in the system memory 2100 and may compress the output data of each layer into the input data of the subsequent layer by using the SCSR algorithm based on the stride of each layer in the ANN.

The storage 2500 may not lose stored data even though power supplied to the computing system 2000 is cut off. For example, the storage 2500 may include non-volatile memory, such as electrically erasable programmable read-only memory (EEPROM), flash memory, phase-change random-access memory (PRAM), resistance random-access memory (RRAM), nano-floating gate memory (NFGM), polymer random-access memory (PoRAM), magnetic random-access memory (MRAM), or ferroelectric random-access memory (FRAM), and may also include storage media, such as magnetic tape, optical disk, or magnetic disk. In some embodiments, the storage 2500 may be removable from the computing system 2000.

In some embodiments, the storage 2500 may store the program 2120 for compressing the output data of each layer into the input data of the subsequent layer by using the SCSR algorithm based on the stride of each layer in the ANN according to at least one embodiment, wherein the program 2120 or at least a portion thereof may be loaded from the storage 2500 into the system memory 2100 before the program 2120 is executed by the processor 2300. In some embodiments, the storage 2500 may store files written in a program language and the program 2120 or at least a portion thereof generated from the file by a compiler and the like may be loaded into the system memory 2100.

The input/output devices 2700 may be configured to include input devices, such as keyboards and pointing devices, and output devices, such as display devices and printers. For example, a user may trigger execution of the program 2120 by the processor 2300 through the input/output devices 2700.

The communication connections 2900 may be configured to provide access to a network external to the computing system 2000. For example, a network may include multiple computing systems and communication links, wherein the communication links may include wired links, optical links, wireless links, or any other type of links.

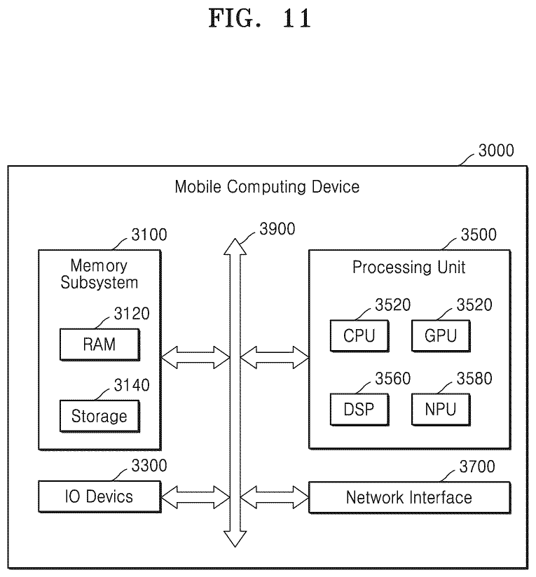

FIG. 11 is a block diagram of a portable computing device according to at least one embodiment.

In some embodiments, a circuit for compressing the output data of each layer into input data of the subsequent layer by using the SCSR algorithm based on the stride of each layer in the ANN may be implemented in the portable computing device 3000. The portable computing device 3000 may include, as a non-limiting example, any portable electronic device powered by a battery or self-generated power, such as a mobile phone, a tablet PC, a wearable device, an Internet of Things device, and the like.

As shown in FIG. 11, the portable computing device 3000 may include a memory subsystem 3100, input/output devices 3300, a processing unit 3500, and a network interface 3700, wherein the memory subsystem 3100, the input/output devices 3300, the processing unit 3500, and the network interface 3700 may communicate with each other through bus 3900. In some embodiments, at least two of the memory subsystem 3100, the input/output devices 3300, the processing unit 3500, and the network interface 3700 may be included in one package as a system-on-a-chip (SoC).

The memory subsystem 3100 may include RAM 3120 and storage 3140. The RAM 3120 and/or storage 3140 may store instructions which are executed by the processing unit 3500 and data which are processed by the processing unit 3500. For example, the RAM 3120 and/or storage 3140 may store variables, such as signals, weights, and biases of the ANN and may store parameters of the artificial neuron (or computational node) of the ANN. In some embodiments, the storage 3140 may include non-volatile memory.

The processing unit 3500 may include a central processing unit (CPU) 3520, a graphics processing unit (GPU) 3540, a digital signal processor (DSP) 3560, and a neural processing unit (NPU) 3580. In some embodiments, the processing unit 3500 may include at least some of the CPU 3520, the GPU 3540, the DSP 3560, and the NPU 3580, which is different from what is shown in FIG. 10.

The CPU 3520 may perform the overall operation of the portable computing device, e.g., directly perform a specific task in response to external input received through the input/output devices 3300 or instruct other components of the processing unit 3500 to perform the task. The GPU 3540 may generate data for an image output through a display device included in the input/output devices 3300 and may encode the data received from a camera included in the input/output devices 3300. The DSP 3560 may generate useful data by processing digital signals, for example, digital signals provided from the network interface 3700.

The NPU 3580, which is dedicated hardware for the ANN, may include a plurality of calculation nodes corresponding to at least some of artificial neurons constituting the ANN, wherein at least some of the plurality of calculation nodes may process signals in parallel. The processing unit 3500 may include the circuit for compressing the output data of each layer into input data of the subsequent layer using the SCSR algorithm based on the stride of each layer in the ANN according to the above embodiments.

The input/output devices 3300 may include input devices, such as a touch input device, a sound input device, and a camera, and output devices, such as a display device and a sound output device. The network interface 3700 may provide the portable computing device 3000 with access to a mobile communication network, such as long-term evolution (LTE) or 5G or with access to a local network, such as Wi-Fi.

While the inventive concepts have been particularly shown and described with reference to embodiments thereof, it will be understood that various changes in form and details may be made therein without departing from the spirit and scope of the following claims.

What is claimed is:

1. A processing circuit comprising:
a computing circuit configured to generate output data for a first layer in an artificial neural network (ANN), the generating output data for the first layer including performing a convolution operation based on input data of the first layer and weight data of the first layer; and
a compressing circuit configured to compress the output data of the first layer into second compressed input data, the compressing of the output data of the first layer including extracting non-zero values from the output data of the first layer based on a stride of a second layer in the artificial neural network and to output the second compressed input data as input data of the second layer,
wherein the extracting non-zero values from the output data of the first layer includes using a stride-aware compressed sparse row (SCSR) algorithm, and
wherein the second layer is a subsequent layer to the first layer.

2. The processing circuit of claim 1, wherein the compressing circuit is configured to compress the output data of the first layer such that a number of pieces of second compressed input data is the same as the stride of the second layer.

3. The processing circuit of claim 2, wherein the output data of the first layer is formed in a matrix form comprising a plurality of elements, and
wherein each of the second compressed input data is composed of elements, from among the plurality of elements, that have a same remainder value when a column index of the plurality of elements is divided by the stride of the second layer.

4. The processing circuit of claim 1, wherein the input data of the first layer comprises the same number of pieces of first compressed input data as a stride of the first layer output, and
wherein the weight data of the first layer comprises the same number of pieces of first compressed weight data as the stride of the first layer generated by using the SCSR algorithm based on the stride of the first layer.

5. The processing circuit of claim 4, wherein the first compressed weight data is generated in an operation of training the artificial neural network.

6. The processing circuit of claim 4, further comprising:
an input circuit configured to store the first compressed input data and the second compressed input data; and
a weight buffer configured to store the first compressed weight data,
wherein the computing circuit comprises a plurality of processing elements (PEs) arranged in a matrix form,
wherein the plurality of PEs are configured such that PEs having the same row index are configured to receive the same compressed input data from the input circuit and PEs having the same column index are configured to receive the same compressed weight data from the weight buffer.

7. The processing circuit of claim 6, wherein the plurality of PEs each comprise:
a multiply-accumulate (MAC) circuit configured to generate output data by performing multiplication and accumulation based on the compressed input data received from the input circuit and the compressed weight data received from the weight buffer;
an address calculating circuit configured to calculate an address of the output data based on an address signal of the compressed input data received from the input circuit;
an output buffer configured to store the address of the output data and the output data; and
a PE controller configured to control the input circuit to transmit a valid element of the compressed input data to the MAC circuit and to control the weight buffer to transmit a valid element of the compressed weight data to the MAC circuit.

8. The processing circuit of claim 7, wherein
the PE controller is further configured to calculate an input counter and a weight counter using a convolution algorithm based on a small array, and
a start element and an end element, of the compressed weight data, control the input circuit to transmit the valid element among the elements of the compressed input data to the MAC circuit based on the input data, and control the weight buffer to transmit the valid element among the elements of the compressed weight data to the MAC circuit based on the weight counter,
wherein the small array refers to an array for selecting an initial value of the input counter,
the start element of the compressed weight data refers to an element with a smallest row index among the valid elements of the compressed input data, and
the end element of the compressed weight data refers to an element with a largest row index among the valid elements of the compressed input data.

9. The processing circuit of claim 8, further comprising:
a main controller configured to
generate the small array, the start element of the compressed weight data, and the end element of the compressed weight data based on the compressed input data, and
transmit the small array, the start element of the compressed weight data, and the end element of the compressed weight data to the PE controller.

10. The processing circuit of claim 1, wherein the second compressed input data is generated in an operation of inferring the artificial neural network.

11. A method of operating a processing circuit, the method comprising:
generating output data for a first layer in an artificial neural network by performing a convolution operation based on input data of the first layer and weight data of the first layer;
extracting non-zero values from the output data of the first layer; and
compressing the output data of the first layer into second compressed input data based on the extracted non-zero values and a stride of a second layer in the artificial neural network,
wherein the second layer is a subsequent layer to the first layer.

12. The method of claim 11, wherein a number of pieces of the second compressed input data is the same as the stride of the second layer.

13. The method of claim 11, wherein the output data of the first layer is formed in a matrix form comprising a plurality of elements, and
wherein the compressing of the output data of the first layer into the second compressed input data comprises composing the second compressed input data of elements, from among the plurality of elements, that have a same remainder value when a column index of the plurality of elements is divided by the stride of the second layer.

14. The method of claim 11, further comprising:
extracting non-zero values from output data of a previous layer, the first layer subsequent to the previous layer; and
compressing the output data of the previous layer into first compressed input data based on the non-zero values extracted from the output data of the previous layer and stride of the first layer,
wherein the input data of the first layer comprises the first compressed input data.

15. The method of claim 14, further comprising:
training the artificial neural network,
wherein the weight data of the first layer is generated based on the stride of the first layer in the training of the artificial neural network and comprises the same number of pieces of first compressed weight data as the stride of the first layer.

16. The method of claim 15, wherein the generating of the output data of the first layer comprises:
determining an input counter and a weight counter based on the first compressed input data;
receiving a valid element of the first compressed weight data and a valid element of the first compressed input data, the valid element of the first compressed weight data based on the weight counter and the valid element of the first compressed input data based on the input counter; and
generating the output data of the first layer by performing the convolution operation based on the valid element of the first compressed input data and the valid element of the first compressed weight data.

17. A system comprising:
at least one processor; and
a non-transitory storage medium storing instructions configured to, when executed by the at least one processor, cause the at least one processor to perform a method of compressing output data of a plurality of layers in an artificial neural network,
wherein the method of compressing the output data of the plurality of layers in the artificial neural network comprises
generating output data of a first layer in the artificial neural network, the generating output data of a first layer in the artificial neural network including performing a convolution operation based on input data of the first layer in the artificial neural network and weight data of the first layer,
extracting non-zero values from the output data of the first layer, and
compressing the output data of the first layer into second compressed input data based on the extracted non-zero values and a stride of a second layer in the artificial neural network,
wherein the second layer is a subsequent layer to the first layer.

18. The system of claim 17, wherein the instructions are configured such that, when executed by the at least one processor, the at least one processor compresses the output data of the first layer such that a number of pieces of second compressed input data is the same as the stride of the second layer.

19. The system of claim 17, wherein the output data of the first layer is formed in a matrix form comprising a plurality of elements, and
wherein the compressing of the output data of the first layer into the second compressed input data comprises composing the second compressed input data of elements, among the plurality of elements, that have the same remainder value when a column index of the plurality of elements is divided by the stride of the second layer.

20. The system of claim 17, wherein the instructions are configured such that, when executed by the at least one processor, the at least one processor further performs:
extracting non-zero values from output data of a previous layer to the first layer; and
compressing the output data of the previous layer into first compressed input data based on the non-zero values extracted from the output data of the previous layer and stride of the first layer,
wherein the input data of the first layer comprises the first compressed input data.
